(19) United States
(12) Patent Application Publication
(10) Pub. No.: US 2009/0242984 A1
(43) Pub. Date: Oct. 1, 2009

(54) Semiconductor device and method of manufacturing the same

(75) Inventor: Kousuke Yoshida, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/379,512

(22) Filed: Feb. 24, 2009

(30) Foreign Application Priority Data
Mar. 26, 2008 (JP) 2008-081620

(51) Int. Cl. H01L 29/78; H01L 21/336

(52) U.S. Cl. 257/346; 438/306; 257/E29.255; 257/E21.409

(57) ABSTRACT

Aimed at providing a semiconductor device capable preventing transistor characteristics from departing from design characteristics, the semiconductor device of the present invention has a gate insulating film and a gate electrode positioned over a channel forming region; two second-conductivity-type, high-concentration impurity diffused layers which function as the source and drain of a transistor; two second-conductivity-type, low-concentration impurity diffused layers having a concentration lower than that of the second-conductivity-type, high-concentration impurity diffused layers, provided respectively around the second-conductivity-type, high-concentration impurity diffused layers, so as to expand the second-conductivity-type, high-concentration impurity diffused layers in the depth-wise direction and the channel-length-wise direction; and a first-conductivity-type buried layer having a concentration higher than that of the semiconductor layer, positioned below the second-conductivity-type, low-concentration impurity diffused layers, and extended from an area below the channel forming region via an area below the device isolation film towards the outer periphery of the device isolation film.

This application is based on Japanese patent application No. 2008-081620 the content of which is incorporated hereinto by reference.

### BACKGROUND

1. Technical Field

The present invention relates to a semiconductor device and a method of manufacturing the same, capable of suppressing transistor characteristics from departing from design characteristics.

Related Art

There is known one example of high-voltage MOS transistor described in Japanese Laid-Open Patent Publication No. 2002-289847. As illustrated by a sectional view in FIG. 7, the transistor is formed to a first-conductivity-type semiconductor layer 300, and has a gate insulating film 330, a gate electrode 340, and second-conductivity-type, high-concentration impurity diffused layers 370 and low-concentration impurity diffused layers 360 which function as the source and the drain. The gate insulating film 330 and the gate electrode 340 are positioned over a channel forming region 380. The low-concentration impurity diffused layers 360 are formed so as to expand the high-concentration impurity diffused layers 370 in the depth-wise direction and in the channel-length-wise direction. The high-concentration impurity diffused layers 370 are formed by ion implantation of an impurity in a self-aligned manner while using the gate electrode 340 as a mask.

In the semiconductor layer having the transistor formed therein, substrate current may sometimes flow from an area positioned below the channel forming region towards the outer periphery of the device forming region. Once such substrate current should flow, the potential in the semiconductor layer positioned below the channel forming region may vary, and thereby the source, the semiconductor layer, and the drain may operate together just like a bipolar transistor. Such operation of bipolar transistor may make the transistor characteristics depart from the design characteristics.

### SUMMARY

According to the present invention, there is provided a semiconductor device which includes;

a device isolation film formed in a first-conductivity-type semiconductor layer;

a device forming region partitioned by the device isolation film;

a channel forming region provided to the device forming region;

a gate insulating film positioned over the channel forming region;

a gate electrode positioned over the gate insulating film;

at least two or more second-conductivity-type, high-concentration impurity diffused layers formed in the device forming region, and function as the source and the drain of a transistor;

second-conductivity-type, low-concentration impurity diffused layers having a concentration lower than that of the second-conductivity-type, high-concentration impurity diffused layers, formed in the device forming region, and provided respectively around the second-conductivity-type, high-concentration impurity diffused layers, so as to expand the second-conductivity-type, high-concentration impurity diffused layers in the depth-wise direction and the channel-length-wise direction; and

a first-conductivity-type buried layer having a concentration higher than that of the semiconductor layer, positioned below the second-conductivity-type, low-concentration impurity diffused layers, and extended from an area below the channel forming region via an area below the device isolation film towards the outer periphery of the device isolation film.

According to the present invention, there is provided also a method of manufacturing a semiconductor device, the method includes:

forming a device isolation film in a first-conductivity-type semiconductor layer so as to partition a device forming region;

forming at least two or more second-conductivity-type, low-concentration impurity diffused layers in the device forming region;

forming a first-conductivity-type buried layer in the semiconductor layer by introducing therein a first-conductivity-type impurity;

forming a gate insulating film and a gate electrode over the device forming region; and

forming second-conductivity-type, high-concentration impurity diffused layer, which function as the source and the drain of a transistor, respectively in the second-conductivity-type, low-concentration impurity diffused layers,

wherein the second-conductivity-type, low-concentration impurity diffused layers expand the second-conductivity-type, high-concentration impurity diffused layers in the depth-wise direction and in the channel-length-wise direction, and

the first-conductivity-type buried layer is positioned below the second-conductivity-type, low-concentration impurity diffused layers, and extended from an area below the gate insulating film via an area below the device isolation film towards the outer periphery of the device isolation film.

According to the present invention, the substrate current flows through the first-conductivity-type buried layer to the outer periphery of the device forming region, so that the potential of the semiconductor layer positioned below the channel forming region may be suppressed from being elevated by the substrate current. As a consequence, two second-conductivity-type, low-concentration impurity diffused layers and the semiconductor layer positioned therebetween may be suppressed from operating as a bipolar transistor. In this way, the transistor characteristics may be suppressed from departing from the design characteristics.

### BRIEF DESCRIPTION OF THE DRAWINGS

The above and other objects, advantages and features of the present invention will be more apparent from the following description taken in conjunction with the accompanying drawings, in which:

FIG. 1 is a sectional view illustrating a configuration of a semiconductor device of a first embodiment;

FIG. 2 is a drawing illustrating respective depth profiles of concentrations of first-conductivity-type and second-conductivity-type impurities as viewed in an A-A′ section of FIG. 1;

FIGS. 3A to 3C are sectional views illustrating a method of manufacturing the semiconductor device of this embodiment;

FIG. 4 is a sectional view illustrating a configuration of a semiconductor device of a second embodiment;

FIGS. 5A and 5B are drawings illustrating depth profiles of concentrations of first-conductivity-type and second-conductivity-type impurities as viewed in an A-A′ section of FIG. 4;

FIGS. 6A and 6B are sectional views showing a configuration of a transistor described in Japanese Laid-Open Patent Publication No. 2002-289847.

FIG. 7 is a sectional view explaining a method of manufacturing a semiconductor device of a third embodiment; and

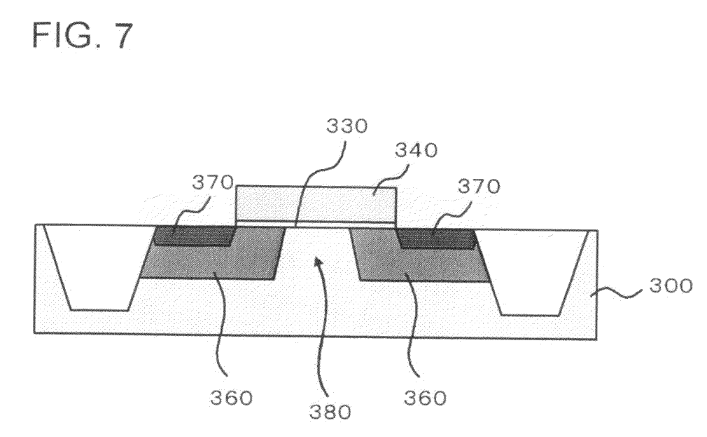

### DETAILED DESCRIPTION

The invention will be now described herein with reference to an illustrative embodiment. Those skilled in the art will recognize that many alternative embodiments can be accomplished using the teachings of the present invention and that the invention is not limited to the embodiment illustrated for explanatory purposes.

Embodiments of the present invention will be explained referring to the attached drawings. Note that any similar constituents will be given with similar reference numerals in all drawings, and explanations therefor will not be repeated.

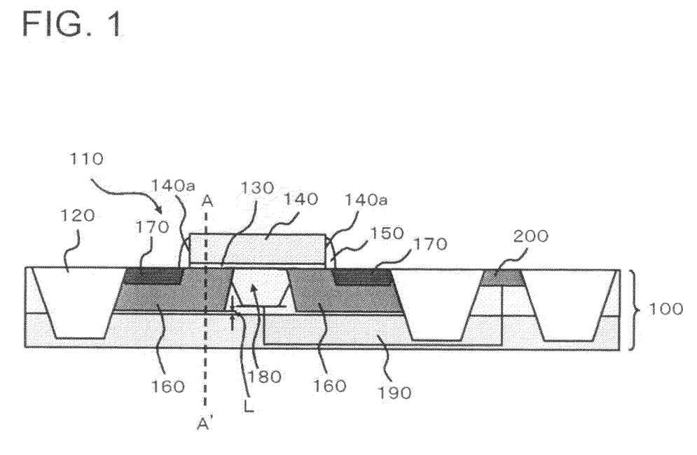

FIG. 1 is a sectional view illustrating a semiconductor device of a first embodiment. The semiconductor device has a semiconductor layer 100, a device isolation film 120 formed in the semiconductor layer 100, a device forming region 110, a channel forming region 180, a gate insulating film 130, a gate electrode 140, at least two or more second-conductivity-type, high-concentration impurity diffused layers 170, at least two or more second-conductivity-type, low-concentration impurity diffused layers 160, and a first-conductivity-type buried layer 190. The semiconductor layer 100 is of a first-conductivity-type. The device forming region 110 is partitioned by the device isolation film 120. The channel forming region 180 is provided to the device forming region 110. The gate insulating film 130 is positioned over the channel forming region 180. The gate electrode 140 is positioned over the gate insulating film 130.

The second-conductivity-type, high-concentration impurity diffused layers 170 are formed in the device forming region 110, and function as the source and drain of a transistor. The second-conductivity-type, low-concentration impurity diffused layers 160 are formed in the device forming region 110, respectively around the second-conductivity-type, high-concentration impurity diffused layers 170. The second-conductivity-type, low-concentration impurity diffused layers 160 are formed so as to expand the second-conductivity-type, high-concentration impurity diffused layers 170 in the depth-wise direction and in the channel-length-wise direction, and have a concentration lower than that of the second-conductivity-type, high-concentration impurity diffused layers 170.

The first-conductivity-type buried layer 190 is formed in the semiconductor layer 100, and extends from an area below the second-conductivity-type, low-concentration impurity diffused layers 160 towards the outer periphery of device isolation film 120. The first-conductivity-type buried layer 190 has an impurity concentration higher than that of the semiconductor layer 100.

In the semiconductor device, substrate current may possibly flows from an area below the channel forming region 180 via the first-conductivity-type buried layer 190 towards the outer periphery of the device forming region 110. As described in the above, the impurity concentration of the first-conductivity-type buried layer 190 is larger than that of the semiconductor layer 100. Therefore, the resistivity against the substrate current flowing towards the outer periphery of the device forming region 110 will be lowered, and thereby the potential of the semiconductor layer 100 positioned below the channel forming region 180 may be suppressed from being elevated by the substrate current. As a consequence, two second-conductivity-type, low-concentration impurity diffused layers 160 and the semiconductor layer 100 positioned therebetween may be suppressed as operating as a bipolar transistor. The transistor characteristics may therefore be suppressed from departing from the design characteristics.

The semiconductor layer 100 is a semiconductor substrate such as silicon substrate, or may be a semiconductor layer of an SOI (Silicon On Insulator) substrate.

In the surficial portion of the semiconductor layer 100, the first-conductivity-type, high-concentration impurity diffused layer 200 is formed. The first-conductivity-type, high-concentration impurity diffused layer 200 is positioned outside the device forming region 110, and has a first-conductivity-type impurity concentration higher than that of the semiconductor layer 100. The first-conductivity-type, high-concentration impurity diffused layer 200 is electrically connected with a contact (not illustrated) which applies the substrate potential. The first-conductivity-type buried layer 190 extends from an area below the channel forming region 180 towards an area below the first-conductivity-type, high-concentration impurity diffused layer 200. The substrate current possibly flows via the first-conductivity-type buried layer 190 towards the first-conductivity-type, high-concentration impurity diffused layer 200.

The transistor illustrated in FIG. 1 is a high-voltage transistor, wherein the gate insulating film 130 is typically composed of a silicon oxide film. In this configuration, the thickness of the gate insulating film 130 is typically 10 nm or larger and 70 nm or smaller. On the side faces of the gate electrode 140, sidewalls 150 are formed.

In this embodiment, the gate electrode 14 has a width in the channel-length-wise direction larger than the channel length, and two side faces 140a are respectively positioned over the second-conductivity-type, low-concentration impurity diffused layers 160 on the different sides. Since portions of the second-conductivity-type, low-concentration impurity diffused layers 160 are positioned below the gate electrode 140, the transistor may be shrunk. The width of the region where the gate electrode 140 and each of the second-conductivity-type, low-concentration impurity diffused layers 160 overlap is typically 0.2 μm or larger and 1.2 μm or smaller.

Note that, if one of the side faces 140a of the gate electrode 140 is positioned over one of the second-conductivity-type, low-concentration impurity diffused layers 160 which functions as the drain, the electric field may concentrate at the lower end of the side face 140a, and thereby the substrate current may be more likely to increase. However, according to this embodiment, even if the substrate current should increase, two second-conductivity-type, low-concentration impurity diffused layers 160 and the semiconductor layer 100 positioned therebetween may be suppressed from operating together as a bipolar transistor as described in the above. The transistor characteristics may therefore be suppressed from departing from the design characteristics.

The boundary between the second-conductivity-type, low-concentration impurity diffused layers 160 and the general semiconductor layer 100 may be defined by, for example, a line across which the concentration of activated second-conductivity-type impurity exceeds the concentration of activated first-conductivity-type impurity. The boundary between the first-conductivity-type buried layer 190 and the general semiconductor layer 100 may be determined, while typically assuming the concentration of activated first-conductivity-type impurity as 1×10¹⁴/cm³.

In the example illustrated in the drawing, the distance L between the first-conductivity-type buried layer 190 and the second-conductivity-type, low-concentration impurity diffused layers 160 is preferably 0 μm or larger and 0.2 μm or smaller, for example. As the distance L decreases, a depletion layer possibly formed in the channel forming region 180 may be less likely to expand in the channel-length-wise direction, thereby punch-through may be suppressed from occurring between two second-conductivity-type, low-concentration impurity diffused layers 160.

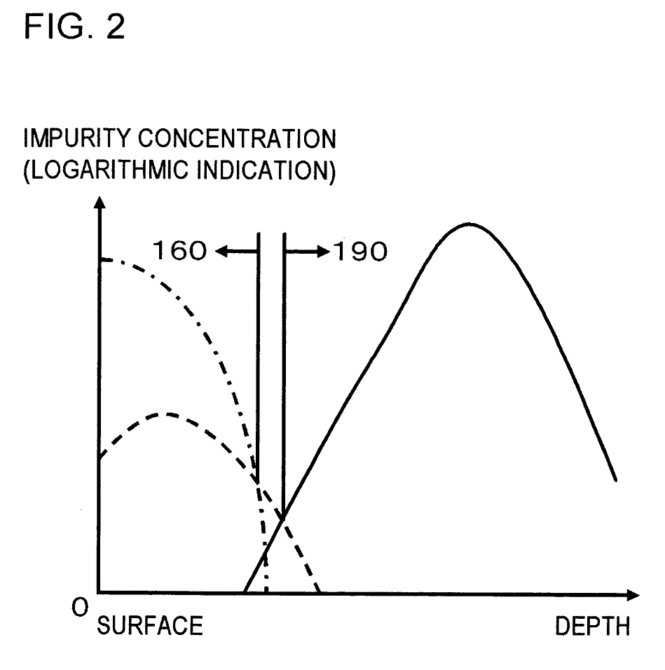

FIG. 2 is a drawing illustrating the respective depth profiles of the concentrations of first-conductivity-type and second-conductivity-type impurities as viewed in an A-A section of FIG. 1. There are implanted, as seen in the A-A section, a first-conductivity-type impurity (broken line) for adjusting the threshold voltage (Vth) of the transistor, a second-conductivity-type impurity (dashed line) for forming the second-conductivity-type, low-concentration impurity diffused layers 160, and first-conductivity-type impurity (solid line) for forming the first-conductivity-type buried layer 190. The point where the broken line and the dashed line intersect represents the boundary between one of the second-conductivity-type, low-concentration impurity diffused layers 160 and the semiconductor layer 100. The depth of the boundary is, for example, 0.3 μm or larger and 1 μm or smaller. The point where the broken line and the solid line intersect represents the boundary between the first-conductivity-type buried layer 190 and the semiconductor layer 100. The impurity concentration at the boundary is typically 1×10¹⁴/cm³ or larger, preferably 1×10¹⁵/cm³ or larger, and more preferably 1×10¹⁶/cm³ or larger.

The peak position in the depth-wise direction of the impurity concentration of the first-conductivity-type buried layer 190, while assuming the lower end of the device isolation film 120 as 0, and also assuming the direction towards the surface of said semiconductor layer as the positive direction, is adjusted preferably to −0.5 μm or above and 0.5 μm or below, and more preferably to −0.3 μm or above and 0.3 μm or below. By this adjustment, any current leakage anticipated between the adjacent transistors, for the case where a plurality of transistors illustrated in FIG. 1 are formed side by side while placing the device isolation film 120 in between, may be suppressed by the contribution of the first-conductivity-type buried layer 190.

The depth of the peak position is typically 1 μm or above and 2 μm or below, and the impurity concentration at the peak position is typically 1×10¹⁷/cm³ or larger.

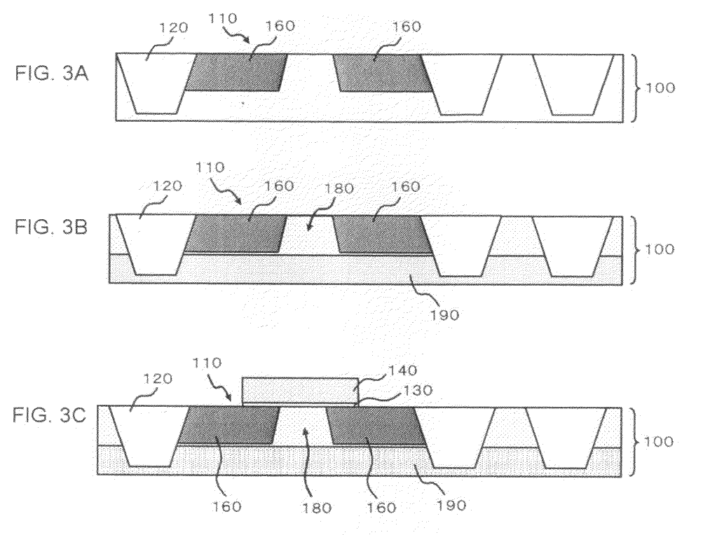

FIGS. 3A to 3C are sectional views illustrating a method of manufacturing the semiconductor device of this embodiment. First, as illustrated in FIG. 3A, the device isolation film 120 is formed in the semiconductor layer 100. The device isolation film 120 may be formed typically by the STI (Shallow Trench Isolation) process, or may be formed by the LOCOS process. Next, a mask pattern (not illustrated) is formed, and a second-conductivity-type impurity is then introduced by ion implantation through the mask pattern. The mask pattern is then removed, and the semiconductor layer 100 is annealed. By these processes, the second-conductivity-type, low-concentration impurity diffused layers 160 are formed.

Next, as shown in FIG. 3B, a first-conductivity-type impurity ion is implanted in a self-aligned manner making use of the device isolation film 120 as a mask. The ion implantation herein is repeated a plurality of times under different ion implantation energies. By these processes, the channel forming region 180 and the first-conductivity-type buried layer 190 are formed. In this process, it may be allowable, for example, to form the first-conductivity-type buried layer 190 first, and to form the channel forming region 180 thereafter.

Next, as shown in FIG. 3C, the gate insulating film 130 and the gate electrode 140 are formed. The gate insulating film 130 is formed, for example, by thermal oxidation.

Thereafter the sidewalls 150 are formed. Next, a second-conductivity-type impurity ion is implanted in a self-aligned manner, to thereby form the second-conductivity-type, high-concentration impurity diffused layers 170 in the second-conductivity-type, low-concentration impurity diffused layers 160. The end portions of each second-conductivity-type, high-concentration impurity diffused layer 170 overlaps each sidewall 150. By these processes, the semiconductor device illustrated in FIG. 1 may be formed.

As has been described in the above, according to this embodiment, the first-conductivity-type buried layer 190 is formed below the transistor. The first-conductivity-type buried layer 190 is formed typically below and around the device forming region 110, and extends from an area below the channel forming region 180 towards the outer periphery thereof. Therefore, resistivity against the substrate current, possibly flowing outside the device forming region 110, may be lowered, and thereby the potential of the semiconductor layer 100 positioned below the channel forming region 180 may be suppressed from being elevated due to the substrate current. As a consequence, two second-conductivity-type, low-concentration impurity diffused layers 160 and the semiconductor layer 100 positioned therebetween may be suppressed from operating together as a bipolar transistor. Accordingly, the transistor characteristics may be suppressed from departing from the design characteristics.

In addition, each of two side faces 140a of the gate electrode 140 is positioned over the second-conductivity-type, low-concentration impurity diffused layers 160 respectively on the different sides. The transistor in this case may be downsized, but may more readily be increased in the substrate current. However, as described in the above, by virtue of formation of the first-conductivity-type buried layer 190, two second-conductivity-type, low-concentration impurity diffused layers 160 and the semiconductor layer 100 positioned therebetween may be suppressed from operating together as a bipolar transistor, despite this structure.

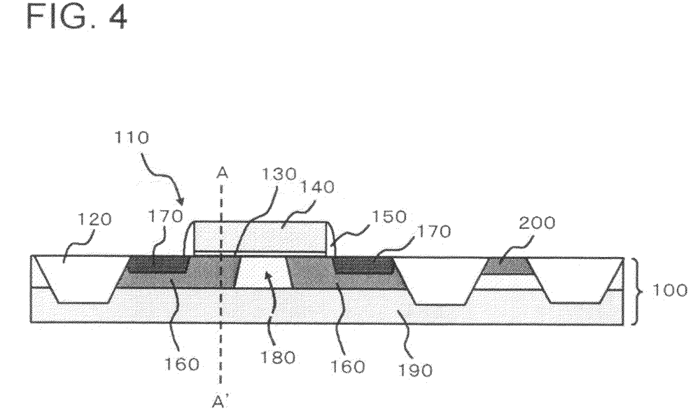

FIG. 4 is a sectional view illustrating a configuration of a semiconductor device according to a second embodiment. The semiconductor device is configured similarly to the semiconductor device shown in the first embodiment, except that the bottom surfaces of the second-conductivity-type, low-concentration impurity diffused layers 160 and the top surface of the first-conductivity-type buried layer 190 are brought into contact. Also a method of manufacturing the semiconductor device according to this embodiment is similar to that shown in the first embodiment.

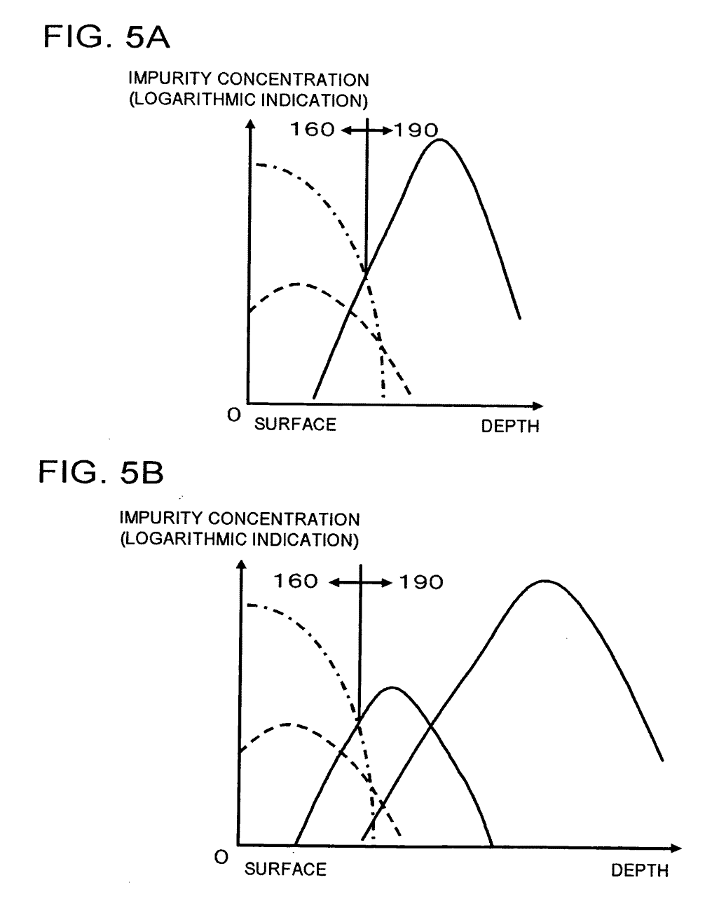

FIGS. 5A and 5B are drawings illustrating the respective depth profiles of the concentrations of first-conductivity-type and second-conductivity-type impurities as viewed in an A-A section of FIG. 4, and correspond to FIG. 2 in the first embodiment.

In the exemplary case illustrated in FIG. 5A, there are implanted, as seen in the A-A section, a first-conductivity-type impurity (broken line) for adjusting the threshold voltage (Vth) of the transistor in the channel forming region 180, a second-conductivity-type impurity (dashed line) for forming the second-conductivity-type, low-concentration impurity diffused layers 160, and a first-conductivity-type impurity (solid line) for forming the first-conductivity-type buried layer 190. In the example illustrated in this drawing, the point where the solid line and the dashed line intersect shifts to higher concentration region, and shallower, as compared with the example illustrated in FIG. 2. For this reason, the first-conductivity-type buried layer 190 and the second-conductivity-type, low-concentration impurity diffused layers 160 come into contact.

An example illustrated in FIG. 5B may be similar to the example illustrated in FIG. 5A, except that the first-conductivity-type impurity (solid line) for forming the first-conductivity-type buried layer 190 is implanted by two steps under a first energy, and a second energy smaller than the first energy. Ion implantation under the second energy is aimed at suppressing punch-through between two second-conductivity-type, low-concentration impurity diffused layers 160, wherein the dose is smaller than the dose under the first energy.

Also in this embodiment, effects similar to those in the first embodiment may be obtained. In addition, the surfaces of the first-conductivity-type buried layer 190 and the semiconductor layer 100 may be brought into close vicinity. Therefore the depletion layer may be further less likely to expand in the channel forming region 180 in the channel-length-wise direction, and thereby, punch-through may be suppressed from occurring between two second-conductivity-type, low-concentration impurity diffused layers 160. As a consequence, the distance between two second-conductivity-type, low-concentration impurity diffused layers 160 may be shortened, and thereby the transistor may further be shrunk.

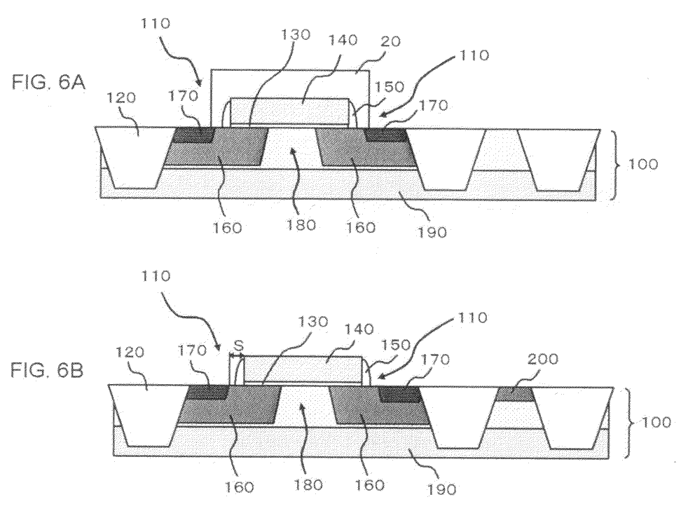

FIGS. 6A and 6B are sectional views explaining a method of manufacturing a semiconductor device of a third embodiment. Processes up to a step of forming the sidewalls 150 in this method of manufacturing a semiconductor device are similar to those in the method of manufacturing a semiconductor device shown in the first embodiment, so that explanations therefor will not be repeated.

After the sidewalls 150 are formed, a mask pattern 20 is formed. Next, a second-conductivity-type impurity ion is implanted, using the mask pattern 20 and the device isolation film 120 as a mask. In this way, the second-conductivity-type, high-concentration impurity diffused layers 170 are formed. The second-conductivity-type, high-concentration impurity diffused layers 170 do not overlap the sidewalls 150. The distance S between each second-conductivity-type, high-concentration impurity diffused layer 170 and the gate electrode 140 is 0.2 μm or larger, and 1 μm or smaller, for example.

Thereafter, as illustrated in FIG. 6B, the mask pattern 20 is removed.

Again by the semiconductor device manufactured in this embodiment, effects similar to those in the first embodiment may be obtained. Since a certain distance may be ensured between each second-conductivity-type, high-concentration impurity diffused layer 170 and each sidewall 150 and consequently the gate electrode 140, voltage resistance of the transistor may be raised.

Embodiments of the present invention have been described in the above referring to the attached drawings, merely as examples of the present invention, while allowing adoption of any configurations other than those described in the above. For example, in the individual embodiments described in the above, the layouts of the second-conductivity-type, high-concentration impurity diffused layers 170 and second-conductivity-type, low-concentration impurity diffused layers 160 are not limited to those illustrated in the individual drawings.

It is apparent that the present invention is not limited to the above embodiment, that may be modified and changed without departing from the scope and spirit of the invention.

What is claimed is:

1. A semiconductor device comprising:
a device isolation film formed in a first-conductivity-type semiconductor layer;
a device forming region partitioned by said device isolation film;
a channel forming region provided to said device forming region;
a gate insulating film positioned over said channel forming region;
a gate electrode positioned over said gate insulating film;
at least two or more second-conductivity-type, high-concentration impurity diffused layers formed in said device forming region, and function as the source and the drain of a transistor;
second-conductivity-type, low-concentration impurity diffused layers having a concentration lower than that of said second-conductivity-type, high-concentration impurity diffused layers, formed in said device forming region, and provided respectively around said second-conductivity-type, high-concentration impurity diffused layers, so as to expand said second-conductivity-type, high-concentration impurity diffused layers in the depth-wise direction and the channel-length-wise direction; and
a first-conductivity-type buried layer having a concentration higher than that of said semiconductor layer, positioned below said second-conductivity-type, low-concentration impurity diffused layer, and extended from an area below said channel forming region via an area below said device isolation film towards the outer periphery of said device isolation film.

2. The semiconductor device as claimed in claim 1,
wherein said gate electrode has the width in the channel-length-wise direction larger than the channel length, and has two side faces respectively positioned over each of two said second-conductivity-type, low-concentration impurity diffused layers.

3. The semiconductor device as claimed in claim 2,
wherein the region where said gate electrode overlap each of said second-conductivity-type, low-concentration impurity diffused layers has a width of 0.2 μm or larger and 1.2 μm or smaller.

4. The semiconductor device as claimed in claim 1,
further comprising a first-conductivity-type, high-concentration impurity diffused layer having a concentration higher than that of said semiconductor layer, formed in said semiconductor layer, while being positioned outside said device forming region,
wherein said first-conductivity-type buried layer is extended from an area below said channel forming region towards an area below said first-conductivity-type, high-concentration impurity diffused layer.

5. The semiconductor device as claimed in claim 1,
wherein said gate insulating film has a thickness of 10 nm or larger and 70 nm or smaller.

6. The semiconductor device as claimed in claim 1,
wherein said first-conductivity-type, high-concentration impurity diffused layer has an impurity concentration of 1×10¹⁴/cm³ or larger, in the regions thereof bounded on other regions.

7. The semiconductor device as claimed in claim 6,
wherein said first-conductivity-type, high-concentration impurity diffused layer has an impurity concentration of 1×10¹⁶/cm³ or larger, in the regions thereof bounded on other regions.

8. The semiconductor device as claimed in claim 1,
wherein the distance between said second-conductivity-type, low-concentration impurity diffused layers and said first-conductivity-type buried layer is 0.2 μm or smaller.

9. The semiconductor device as claimed in claim 1,
wherein in the depth-wise direction of said semiconductor layer,
said first-conductivity-type buried layer has a peak position of impurity concentration of −0.5 μm or above and 0.5 μm or below, assuming the lower end of said device isolation film as 0, and also assuming the direction towards the surface of said semiconductor layer as the positive direction.

10. A method of manufacturing a semiconductor device comprising:
forming a device isolation film in a first-conductivity-type semiconductor layer so as to partition a device forming region;
forming at least two or more second-conductivity-type, low-concentration impurity diffused layers in said device forming region;
forming a first-conductivity-type buried layer in said semiconductor layer by introducing therein a first-conductivity-type impurity;
forming a gate insulating film and a gate electrode over said device forming region; and
forming second-conductivity-type, high-concentration impurity diffused layers, which function as the source and the drain of a transistor, respectively in said second-conductivity-type, low-concentration impurity diffused layers,
wherein said second-conductivity-type, low-concentration impurity diffused layers expand said second-conductivity-type, high-concentration impurity diffused layers in the depth-wise direction and in the channel-length-wise direction, and
said first-conductivity-type buried layer is positioned below said second-conductivity-type, low-concentration impurity diffused layer, and extended from an area below said gate insulating film via an area below said device isolation film towards the outer periphery of said device isolation film.
